(19) United States
(12) Patent Application Publication
(10) Pub. No.: US 2019/0207074 A1
(43) Pub. Date: Jul. 4, 2019

(54) THERMAL BAROMETRIC ALTIMETER

(71) Applicant: National Kaohsiung University of Science and Technology, Kaohsiung City (TW)

(72) Inventors: Chung-Nan Chen, New Taipei City (TW); Wen-Yuan Lan, Tainan City (TW)

(73) Assignee: National Kaohsiung University of Science and Technology, Kaohsiung City (TW)

(21) Appl. No.: 15/983,979

(22) Filed: May 18, 2018

(30) Foreign Application Priority Data
Jan. 2, 2018 (TW) 107100043

(51) Int. Cl. H01L 35/32; H01L 35/34; G01C 5/06

(52) U.S. Cl. CPC H01L 35/32; G01C 5/06; H01L 35/34

(57) ABSTRACT

A thermal barometric altimeter has a base, a suspension structure, and a sensing layer. The suspension structure is formed on the base and a cavity is formed between the base and the suspension structure. A depth of the cavity is equal to or shallower than 1 micrometer. The suspension structure has at least one etch window to form a suspension part and at least one supporting part. The cavity is below the at least one etch window and communicates with the at least one etch window. The sensing layer is formed on a top surface of the suspension part and a top surface of the at least one supporting part.

### BACKGROUND OF THE INVENTION

### 1. Field of the Invention

The present invention relates to an altimeter, and more particularly to a thermal barometric altimeter.

### 2. Description of Related Art

A conventional barometric altimeter employs piezoresistive effect. For example, U.S. Pat. No. 7,908,921 discloses a device having a substrate, a buried cavity formed in the substrate, a flexible membrane suspended over the buried cavity, and piezoresistive elements mounted on the flexible membrane. The piezoresistive elements are connected in a Wheatstone-bridge configuration. When the atmospheric pressure sustained by the device is larger than or lower than the air pressure within the buried cavity, the flexible membrane may be deformed due to air pressure unbalancing, such that the resistors of the piezoresistive elements vary with the deformation of the flexible membrane. The Wheatstone-bridge configuration may detect the resistor change of the piezoresistive elements and correspondingly output a voltage signal for reflecting the atmospheric pressure sustained by the device.

However, the conventional barometric altimeter has shortcomings including:

1. The flexible membrane may have a large area that is difficult to be minimized, and thereby the cost for the flexible membrane is hard to be reduced.

2. The flexible membrane may be manufactured by backside-etching technique of micro-electro-mechanical system (MEMS) that employs a specific double-sided alignment and exposure machine. However, the backside-etching technique is incompatible for standard manufacturing processes in semiconductor foundries. The process to manufacture the flexible membrane is complicated.

3. The conventional device has to be packaged in a sealed space under a standard air pressure in order to keep the air pressure within the buried cavity constant, such that the flexible membrane may be deformed due to air pressure unbalancing when being situated in different atmospheric pressure environments. However, the packaging process for the conventional device is complicated with high cost.

4. The measurement of the conventional device relies on the flexible membrane to be deformed for detecting air pressure. However, reliability problem may occur when the flexible membrane has deformed several times, and thereby the signal outputted from the conventional device may be distorted or the conventional device may be out of function. For example, the reason that the pressure unbalancing on the edge of the flexible membrane is too much or the flexible membrane is frequently bent may damage the flexible membrane or change properties of the flexible membrane.

### SUMMARY OF THE INVENTION

An objective of the present invention is to provide a thermal barometric altimeter to overcome the shortcomings of the conventional barometric altimeter employing piezoresistive effect.

The thermal barometric altimeter of the present invention comprises a base, a suspension structure, and a sensing layer. The suspension structure is formed on the base and a cavity is formed between the base and the suspension structure. A depth of the cavity is equal to or shallower than 1 micrometer. The suspension structure has at least one etch window to form a suspension part and at least one supporting part. The cavity is below the at least one etch window and communicates with the at least one etch window. The sensing layer is formed on a top surface of the suspension part and a top surface of the at least one supporting part.

Compared with the conventional device as mentioned above, the effects of the thermal barometric altimeter of the present invention include:

1. The suspension part has a small area and simple structure. For example, the sensing area of the altimeter of the present invention may be 40 (μm)×40 (μm) that may be 156 times smaller than the sensing area in 500 (μm)×500 (μm) of the conventional device. Hence, the cost of the altimeter of the present invention may be lower than the cost of the conventional device.

2. The process to manufacture the altimeter of the present invention is highly compatible for CMOS (Complementary Metal-Oxide-Semiconductor) manufacturing processes. For example, the altimeter of the present invention may be manufactured by the process “TSMC 0.35 μm mixed-signal 2P4M” provided by Chip Implementation Center (CIC) of Taiwan. Hence, the process to manufacture the altimeter of the present invention is compatible for standard manufacturing processes in semiconductor foundries.

3. In the present invention, the cavity communicates with the at least one etch window. Therefore, the altimeter of the present invention does not have the buried cavity as disclosed in the conventional device, such that the present invention may avoid the problems including complicated packaging process with high cost induced by the buried cavity of the conventional device.

4. The property of the altimeter of the present invention is closely linked to the thermal conductance of the suspension part. In particular, according to the feature that the depth of the cavity is equal to or shallower than 1 micrometer to measure the electric property of the sensing layer for estimating the altitude where the altimeter of the present invention is situated, the measurement of the altimeter of the present invention does not rely on a flexible membrane to be deformed as the conventional device for detecting air pressure, and thereby the present invention does not have the reliability problem induced by the flexible membrane.

### BRIEF DESCRIPTION OF THE DRAWINGS

FIG. 1 is a top view of a first embodiment in accordance with the present invention;

FIG. 2 is a cross-sectional view of the first embodiment in accordance with the present invention;

FIG. 3 is a characteristic curve diagram showing the total thermal conductance for different depths of the cavity under different air pressures;

FIG. 4 is a top view of a second embodiment in accordance with the present invention;

FIG. 5 is a cross-sectional view of the second embodiment in accordance with the present invention;

FIG. 6 is a top view of the etch windows of the second embodiment in accordance with the present invention;

FIG. 7 is a top view of a third embodiment in accordance with the present invention;

FIG. 8 is a cross-sectional view of the third embodiment in accordance with the present invention;

FIG. 9 is a top view of a fourth embodiment in accordance with the present invention; and

FIG. 10 is a cross-sectional view of the fourth embodiment in accordance with the present invention.

### DETAILED DESCRIPTION OF THE PREFERRED EMBODIMENT

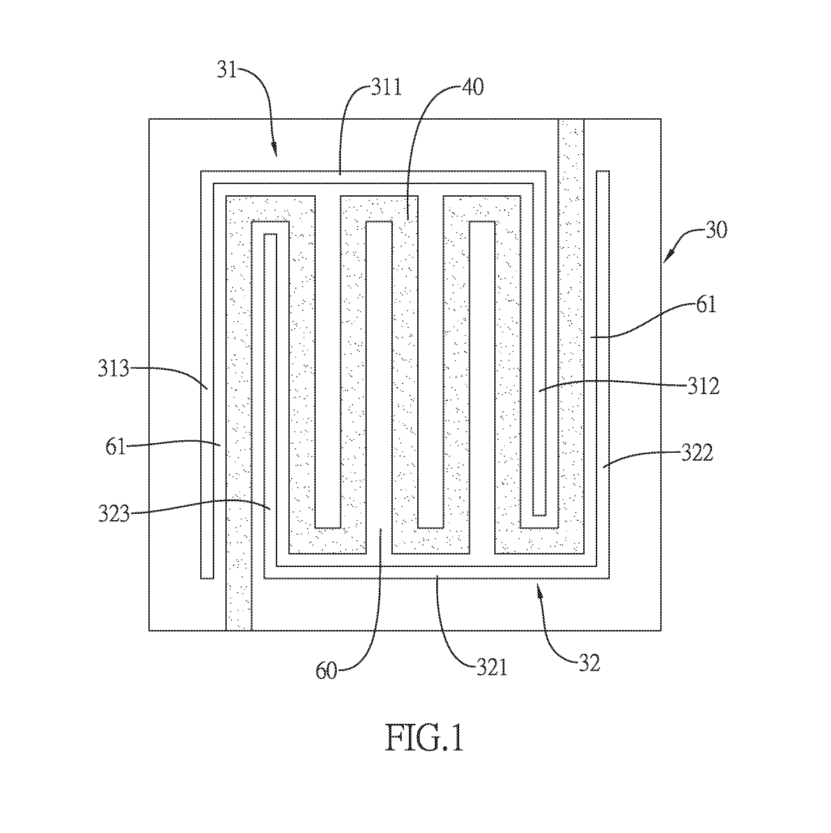

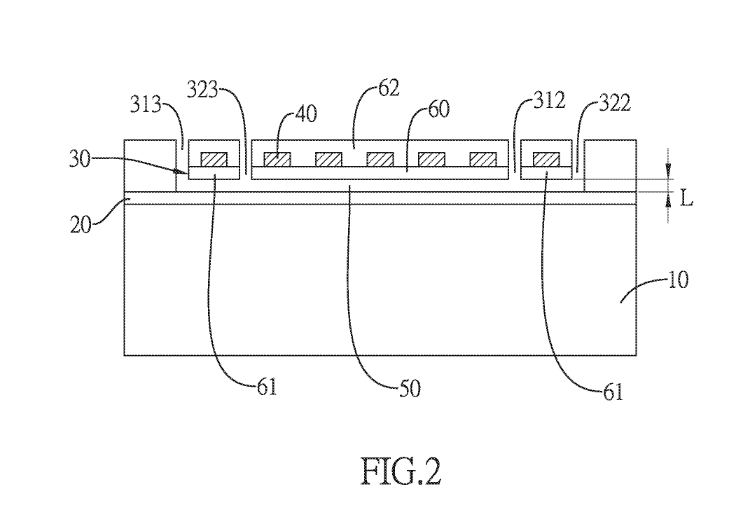

The thermal barometric altimeter of the present invention comprises a base, a suspension structure, and a sensing layer. With reference to FIGS. 1 and 2, a top view and a cross-sectional view of a first embodiment of the present invention are disclosed, wherein the structures of both figures are for illustrative purpose only and do not completely correspond to each other. The base may comprise a substrate 10 and a first insulating layer 20. The suspension structure may comprise a second insulating layer 30. The sensing layer 40 is formed on the suspension structure.

The substrate 10 may be a monocrystalline silicon substrate or a wafer with established integrated circuit layout. The first insulating layer 20 is formed on a top surface of the substrate 10. A cavity 50 is formed between the base and the suspension structure. The second insulating layer 30 is formed over the first insulating layer 20 and has the at least one etch window. In the first embodiment, the at least one etch window comprises a first etch window 31 and a second etch window 32 opposite to the first etch window 31. The cavity 50 is formed between the first insulating layer 20 and the second insulating layer 30. The cavity 50 is below the first etch window 31 and the second etch window 32 and communicates with the first etch window 31 and the second etch window 32. A depth (L) of the cavity 50 is equal to or shallower than 1 micrometer (μm). The depth (L) of the cavity 50 is a distance from a bottom surface of the second insulating layer 30 to a top surface of the first insulating layer 20. The suspension structure (such as the second insulating layer 30) has the first etch window 31 and the second etch window 32 to form a suspension part 60 and at least one supporting part. In the first embodiment, the at least one supporting part comprises multiple supporting parts 61 including a first supporting part and a second supporting part.

With reference to FIG. 1, the first etch window 31 comprises a first straight groove 311, a second straight groove 312, and a third straight groove 313. The first straight groove 311 has two terminals opposite to each other. The second straight groove 312 and the third straight groove 313 perpendicularly and respectively extend toward the second etch window 32 from the two terminals of the first straight groove 311 of the first etch window 31. Similarly, the second etch window 32 comprises a first straight groove 321, a second straight groove 322, and a third straight groove 323. The first straight groove 321 of the second etch window 32 is parallel to the first straight groove 311 of the first etch window 31 and has two terminals opposite to each other. The second straight groove 322 and the third straight groove 323 perpendicularly and respectively extend toward the first etch window 31 from the two terminals of the first straight groove 321 of the second etch window 32.

The second insulating layer 30 has the suspension part 60 formed in a region surrounded by the first straight groove 311 and the second straight groove 312 of the first etch window 31 and the first straight groove 321 and the third straight groove 323 of the second etch window 32. The second insulating layer 30 has the first supporting part formed in a region between the second straight groove 312 of the first etch window 31 and the second straight groove 322 of the second etch window 32. The second insulating layer 30 has the second supporting part formed in a region between the third straight groove 313 of the first etch window 31 and the third straight groove 323 of the second etch window 32. The supporting parts 61 are respectively connected to opposite sides of the suspension part 60. Hence, the suspension part 60 may be a suspension thin film supported by the supporting parts 61 over the cavity 50.

The sensing layer 40 is formed on the top surface of the suspension part 60 and the top surfaces of the supporting parts 61 of the second insulating layer 30. The sensing layer 40 on the suspension part 60 may be, but not limited to, a continuously bent configuration comprising multiple bent segments. The sensing layer 40 may be a component made of an electrically conductive material and resistance of the sensing layer 40 is a function of temperature. For example, the sensing layer 40 may be made of, but not limited to, tungsten or aluminum. In other embodiments, the sensing layer 40 may be a thermocouple.

With reference to FIG. 2, the suspension structure comprises an outer insulating layer 62 formed on the suspension part 60 and the at least one supporting part 61 and covering the sensing layer 40 to protect the sensing layer 40.

The sensing layer 40 is provided to be electrically connected to a measurement device. The measurement device may output a bias to the sensing layer 40 to control the temperature of the sensing layer 40. Because the Joule heat of the sensing layer 40 is difficult to dissipate, the operating temperature of the sensing layer 40 may be higher than room temperature. When the altitude where the altimeter of the present invention is situated changes, environmental air pressure around the altimeter changes too. As a result, air molecule density may be varied with the change of the altitude to affect the heat-dissipating ability of the altimeter of the present invention via air molecules, causing temperature and resistance of the sensing layer 40 to change, too. Therefore, the present altitude where the altimeter of the present invention is situated may be estimated by measuring the resistance variation of the sensing layer 40.

In detail, the sensing layer 40 may have a resistance (R) as an initial value. When a bias (V) is applied to the sensing layer 40, Joule heat (V²/R) would be generated. After the Joule heat is dissipated via any heat-dissipating mechanism to reach a heat balancing status, the temperature of the sensing layer 40 would be increased. The heat-dissipating mechanism may be represented as a heat flow equation as follows:

$$C \frac{dT}{dt} + G ( T - {T}_{a} ) = \frac{{V}^{2}}{R}$$

In the above equation, C is the heat capacity of the altimeter, T is the temperature of the sensing layer 40, t is time, G is the total thermal conductance of the altimeter, and Tₐ is the environmental temperature. The measurement property of the thermal barometric altimeter is determined according to thermal conducting mechanism of the thermal barometric altimeter. When the suspension part 60 with good thermal insulation is heated, the heat conducting paths may include three types such as:

1. Solid conductance (Gs)

The heat of the microstructure of the sensing layer 40 on the suspension part 60 is dissipated via the supporting parts 61. The solid conductance (Gs) may be represented as:

$${G}_{s} = {k}_{s} \frac{wd}{l}$$

In the above equation, kₛ is the thermal conductivity of the supporting part 61, w is the width of the supporting part 61, d is the thickness of the supporting part 61, and l is the length of the supporting part 61.

2. Radiation conductance (Gr)

Radiation conductance is the thermal exchange between the microstructure of the heated sensing layer 40 and the environment. The radiation conductance (Gr) may be represented as:

Gᵣ=(εₜ+ε_{b})σAₛ(T²+Tₐ²)(T+Tₐ)

In the above equation, εₜ and ε_{b} are heat radiating rates on a top surface and a bottom surface of the microstructure of the sensing layer 40 respectively, σ is Stefan-Boltzmann constant, Aₛ is the area of the microstructure of the sensing layer 40, T is the temperature of the sensing layer 40, and Tₐ is the environmental temperature. When the temperature of the sensing layer 40 is rising, the radiation conductance (Gr) may be increased apparently.

3. Gas conductance (Gg)

Thermal conduction is performed within the heated sensing layer 40, the substrate 10, and the air molecules between the sensing layer 40 and the substrate 10. In a range with higher pressure, because the mean free path of the air molecule is far lower than the size of the altimeter, the gas conductance is a viscous flow conductance, such that the gas conductance is irrelevant to air pressure. On the contrary, in a range with lower pressure, because the mean free path of the air molecule is higher than the size of the altimeter, the gas conductance is a molecule flow conductance. As a result, the air molecules collide with the device and heat-draining body to perform the thermal conduction, and thereby the gas conductance is a function of air pressure (P). The traditional Pirani Gauge employs the mechanism as mentioned above to sense air pressure. The relation for the gas conductance and the air pressure may be represented as:

$${G}_{g} = {κ A}_{s} P ( \frac{{P}_{t}}{P + {P}_{t}} )$$

In the above equation, κ is a constant having relation with the property of the air molecules, Aₛ is the area of the microstructure of the sensing layer 40, P is the air pressure, and Pₜ is the transition pressure. The gas conductance may be a compounded conductance including the viscous flow conductance and the molecule flow conductance under the transition pressure. The transition pressure Pₜ is inversely proportional to the depth (L) of the cavity 50 as shown in FIG. 2.

Hence, the total thermal conductance (G) of the altimeter is the sum of the solid conductance (Gs), the radiation conductance (Gr), and the gas conductance (Gg) and may be represented as G=Gs+Gg+Gr.

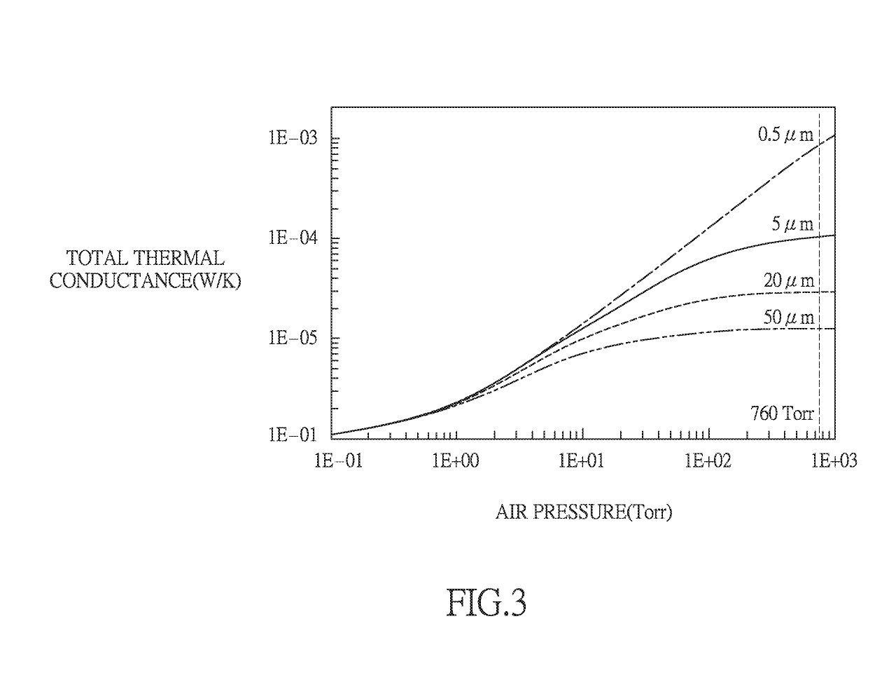

With reference to FIG. 3, according to the analysis for the thermal conductance as mentioned above, it is to be understood that the gas conductance (Gg) is closely linked to the transition pressure (Pₜ.) The transition pressure (Pₜ) is inversely proportional to the depth (L) of the cavity 50 as shown in FIG. 2. In other words, in order to extend the upper limit of the pressure sensing range of the altimeter, the depth (L) of the cavity 50 has to be reduced. FIG. 3 discloses the relationship between the total thermal conductance and the air pressure according to the cavity 50 in different depths including 0.5 μm, 5 μm, 20 μm, and 50 μm. Under a lower air pressure, the effect induced by the depth (L) of the cavity 50 to the total thermal conductance is limited. Oppositely, under a higher air pressure, the total thermal conductance would be extended and increased with the decrease of the depth (L) of the cavity 50, such that the transition would be extended to higher pressure. For example, when the depth (L) of the cavity 50 is 0.5 μm, the upper limit for sensing the air pressure may be extended to 1 atm (760 Torr).

The altimeter of the present invention may be manufactured by the process “TSMC 0.35 μm mixed-signal 2P4M” provided by Chip Implementation Center (CIC) of Taiwan. The sensing materials may be tungsten or aluminum with positive temperature coefficient. The gap between the sensing structure and the heat-draining body would be reduced by employing surface micromachining technique. The sensing area of the altimeter of the present invention may be 40 (μm)×40 (μm) that may be 156 times smaller than the sensing area in 500 (μm)×500 (μm) of the conventional barometric altimeter employing piezoresistive effect. The sensitivity of the altimeter of the present invention may be 3 μV/m and the height resolution of the altimeter of the present invention may be 1 meter.

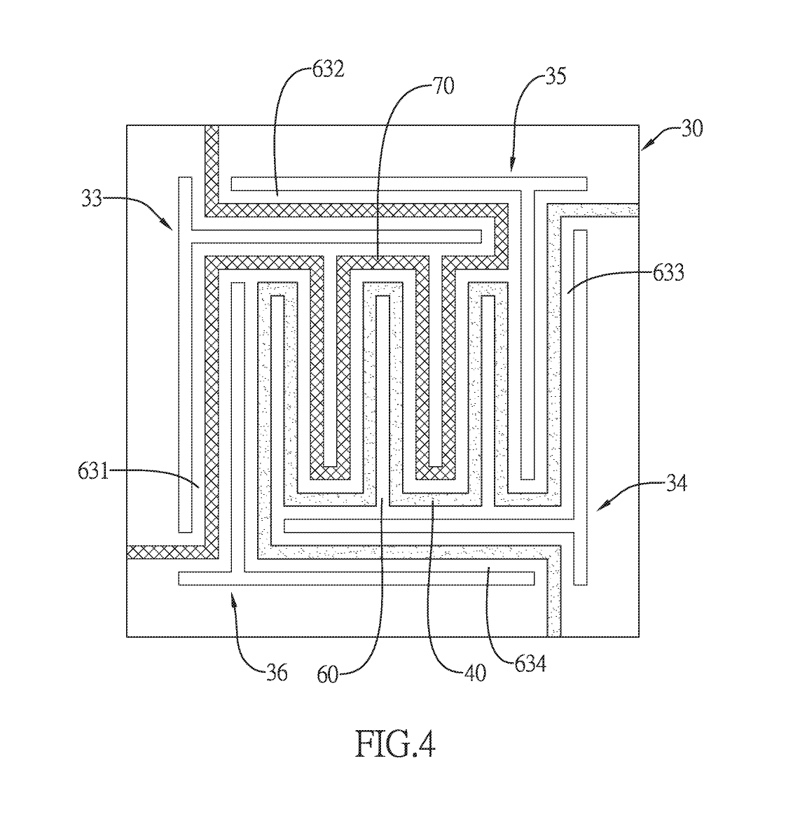

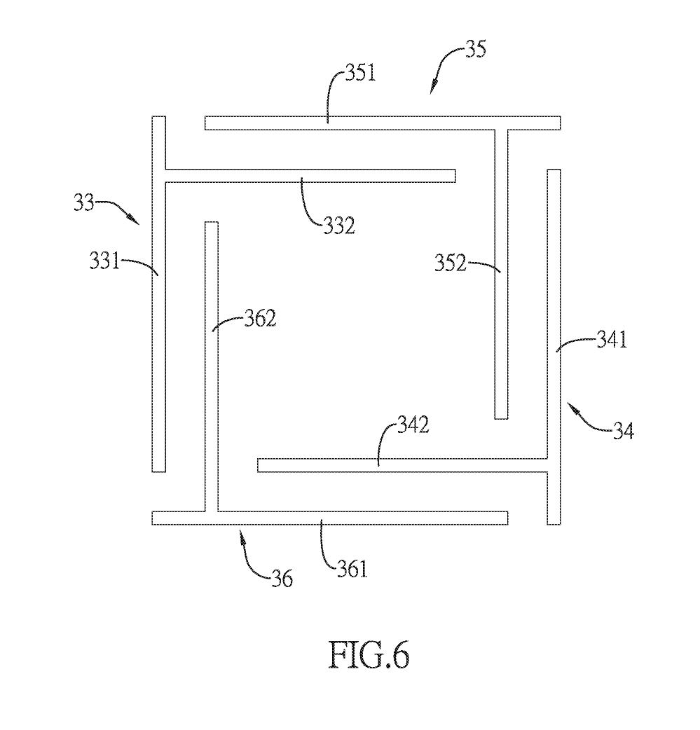

With reference to FIGS. 4-6, a second embodiment of the present invention is disclosed. The second embodiment further comprises a heating resistor layer 70. The heating resistor layer 70 may be a component made of an electrically conductive material such as metal, alloy, semiconductor, or metal compound. As shown in FIGS. 4-6, in the second embodiment. the at least one etch window comprises a first etch window 33, a second etch window 34, a third etch window 35, and a fourth etch window 36. The first etch window 33 is opposite to the second etch window 34 and comprises a first straight groove 331 and a second straight groove 332 perpendicularly extending toward the second etch window 34 from the first straight groove 331 of the first etch window 33. The second etch window 34 comprises a first straight groove 341 and a second straight groove 342 perpendicularly extending toward the first etch window 33 from the first straight groove 341 of the second etch window 34. The first straight groove 331 of the first etch window 33 is parallel to the first straight groove 341 of the second etch window 34. The second straight groove 332 of the first etch window 33 is dislocated from and parallel to the second straight groove 342 of the second etch window 34. The third etch window 35 and the fourth etch window 36 are between the first etch window 33 and the second etch window 34. The third etch window 35 is opposite to the fourth etch window 36 and comprises a first straight groove 351 and a second straight groove 352 perpendicularly extending toward the fourth etch window 36 from the first straight groove 351 of the third etch window 35. The fourth etch window 36 comprises a first straight groove 361 and a second straight groove 362 perpendicularly extending toward the third etch window 35 from the first straight groove 361 of the fourth etch window 36. The first straight groove 351 of the third etch window 35 is parallel to the first straight groove 361 of the fourth etch window 36. The second straight groove 352 of the third etch window 35 is dislocated from and parallel to the second straight groove 362 of the fourth etch window 36.

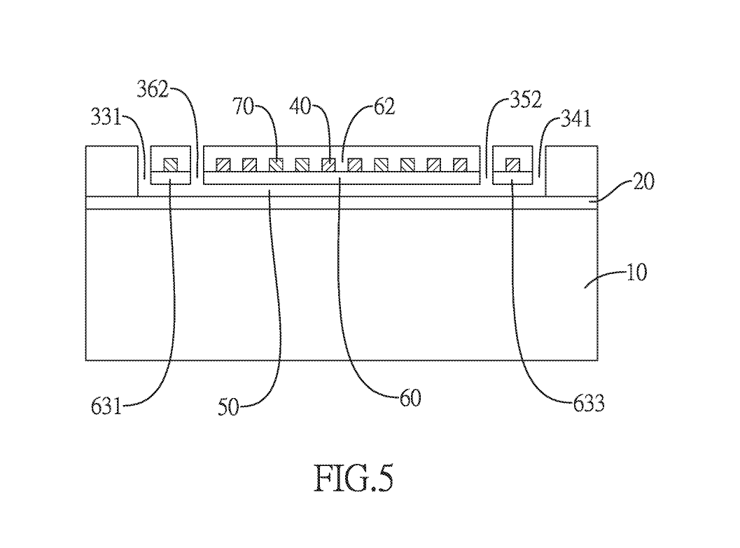

With reference to FIGS. 4 and 5, the second insulating layer 30 has the suspension part 60 formed in a region surrounded by the second straight grooves 332, 342, 352, 362 of the first to fourth etch windows 33, 34, 35, 36. In the second embodiment, the at least one supporting part comprises a first supporting part 631, a second supporting part 632, a third supporting part 633, and a fourth supporting part 634. The second insulating layer 30 has the first supporting part 631 formed in a region between the first straight groove 331 of the first etch window 33 and the second straight groove 362 of the fourth etch window 36. The second insulating layer 30 has the second supporting part 632 formed in a region between the first straight groove 351 of the third etch window 35 and the second straight groove 332 of the first etch window 33. The second insulating layer 30 has the third supporting part 633 formed in a region between the first straight groove 341 of the second etch window 34 and the second straight groove 352 of the third etch window 35. The second insulating layer 30 has the fourth supporting part 634 formed in a region between the first straight groove 361 of the fourth etch window 36 and the second straight groove 342 of the second etch window 34.

The sensing layer 40 is formed on the top surface of the suspension part 60 and the top surfaces of the third supporting part 633 and the fourth supporting part 634 of the second insulating layer 30. In the second embodiment, the sensing layer 40 is a thermocouple layer. The sensing layer 40 on the suspension part 60 is, but not limited to, a continuously bent configuration comprising multiple bent segments. The heating resistor layer 70 is formed on the top surface of the suspension part 60 and the top surfaces of the first supporting part 631 and the second supporting part 632 of the second insulating layer 30. The heating resistor layer 70 on the suspension part 60 is, but not limited to, a continuously bent configuration comprising multiple bent segments. The multiple bent segments of the sensing layer 40 and the multiple bent segments of the heating resistor layer 70 are alternately disposed.

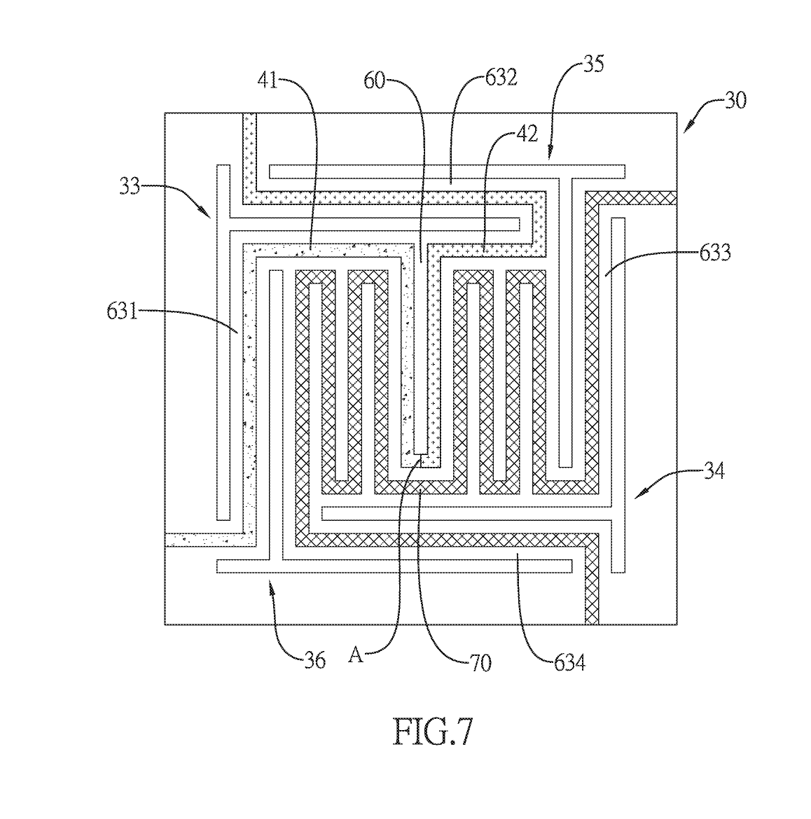

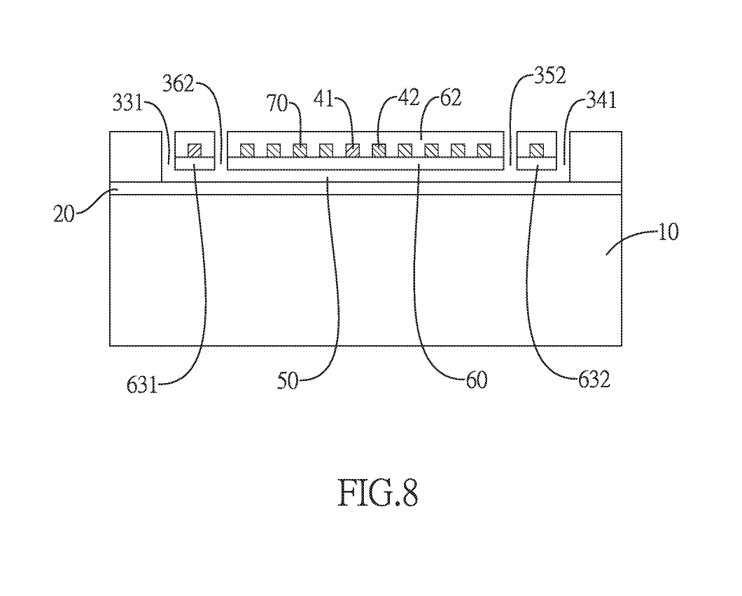

With reference to FIGS. 7 and 8, a third embodiment of the present invention is disclosed. The suspension part 60 and the supporting parts 631-634 in the third embodiment may be referred to the second embodiment and would not be repeated herein. In the third embodiment, the heating resistor layer 70 is formed on the top surface of the suspension part 60 and the top surfaces of the third supporting part 633 and the fourth supporting part 634 of the second insulating layer 30. The heating resistor layer 70 on the suspension part 60 is, but not limited to, a continuously bent configuration comprising multiple bent segments. The sensing layer 40 is formed on the top surface of the suspension part 60 and the top surfaces of the first supporting part 631 and the second supporting part 632 of the second insulating layer 30. In the third embodiment, the sensing layer 40 comprises a first thermocouple member 41 and a second thermocouple member 42. The first thermocouple member 41 has a first terminal formed on the first supporting part 631 and a second terminal formed on the suspension part 60. The second thermocouple member 42 has a first terminal formed on the second supporting part 632 and a second terminal formed on the suspension part 60. The second terminal of the first thermocouple member 41 and the second terminal of the second thermocouple member 42 are connected to each other to form a junction (A) on the suspension part 60. The junction (A) may be located in one of the multiple bent segments of the heating resistor layer 70.

In the second embodiment and the third embodiment, when a bias is applied to the heating resistor layer 70, the temperature of the heating resistor layer 70 would be increased, and thereby the altimeter may operate at higher temperature (higher than room temperature). When the altitude where the altimeter is situated changes, the temperature of the sensing layer 40 changes due to the change of the heat-dissipating ability of the altimeter, and the resistance of the sensing layer 40 changes, too. Therefore, the present altitude where the altimeter is situated may be estimated by measuring the resistance variation of the sensing layer 40.

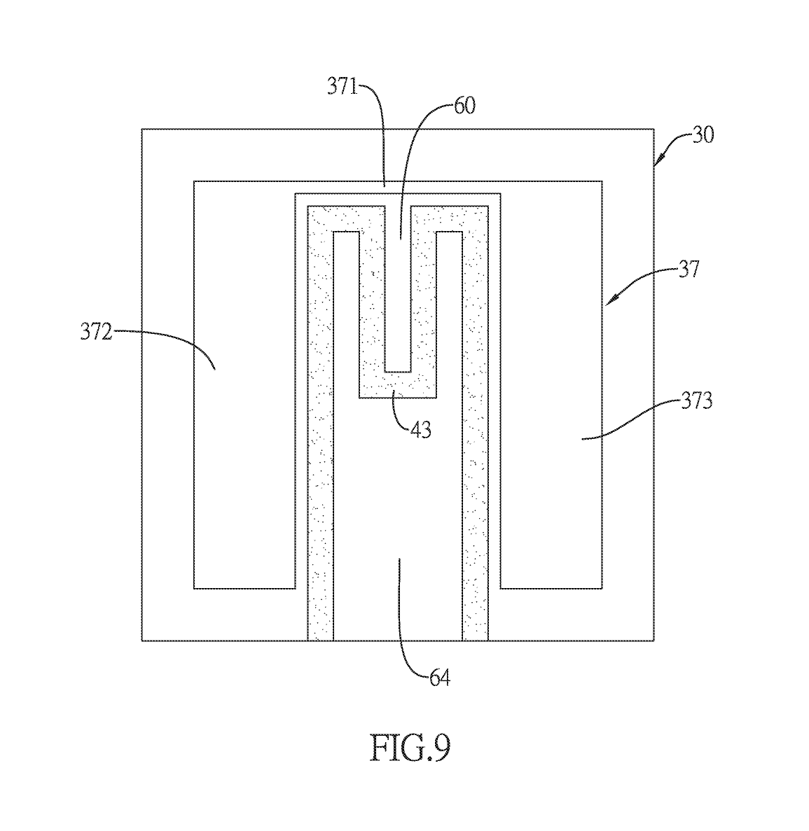

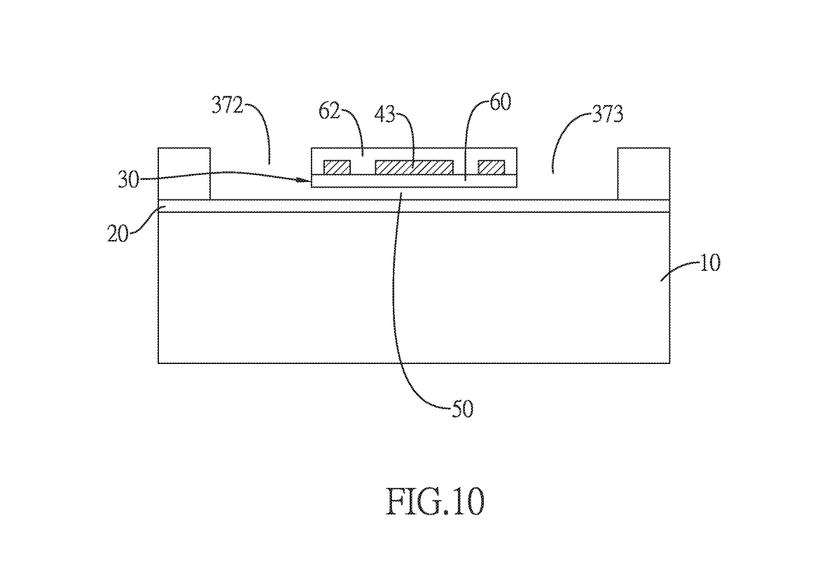

With reference to FIGS. 9 and 10, a fourth embodiment of the present invention is disclosed. In the fourth embodiment, the at least one etch window is one etch window 37 and the at least one supporting part is one supporting part 64. The etch window 37 comprises a first straight groove 371, a second straight groove 372, and a third straight groove 373. The first straight groove 371 has two terminals opposite to each other. The second straight groove 372 and the third straight groove 373 perpendicularly and respectively extend toward a same direction from the two terminals of the first straight groove 371. The second insulating layer 30 has the suspension part 60 and the supporting part 64 formed in a region between the second straight groove 372 and the third straight groove 373. The suspension part 60 is closer to the first straight groove 371 than the suspension part 64. The sensing layer 43 is a component made of an electrically conductive material and resistance of the sensing layer is a function of temperature. The sensing layer 43 is formed on the top surfaces of the suspension part 60 and the supporting part 64. The sensing layer 43 on the suspension part 60 is, but not limited to, a continuously bent configuration comprising multiple bent segments.

The sensing layer 43 is provided to be electrically connected to a measurement device. The measurement device may output a bias to the sensing layer 43 to control the temperature of the sensing layer 43. When the altitude where the altimeter is situated changes, air molecule density may be varied with the change of the altitude to affect the heat-dissipating ability of the altimeter via air molecules, causing temperature and resistance of the sensing layer 43 to change, too. Therefore, the present altitude where the altimeter of the present invention is situated may be estimated by measuring the resistance variation of the sensing layer 43.

What is claimed is:

1. A thermal barometric altimeter comprising:
a base;
a suspension structure formed on the base and a cavity formed between the base and the suspension structure, wherein
a depth of the cavity is equal to or shallower than 1 micrometer;
the suspension structure has at least one etch window to form a suspension part and at least one supporting part; and
the cavity is below the at least one etch window and communicates with the at least one etch window; and
a sensing layer formed on a top surface of the suspension part and a top surface of the at least one supporting part.

2. The thermal barometric altimeter as claimed in claim 1, wherein
the base comprises a substrate and a first insulating layer formed on a top surface of the substrate;
the suspension structure comprises a second insulating layer formed over the first insulating layer and has the at least one etch window; and
the depth of the cavity is a distance from a bottom surface of the second insulating layer to a top surface of the first insulating layer.

3. The thermal barometric altimeter as claimed in claim 2, wherein
the at least one etch window comprises a first etch window and a second etch window opposite to the first etch window;
the first etch window comprises a first straight groove, a second straight groove, and a third straight groove, the first straight groove of the first etch window has two terminals opposite to each other, and the second straight groove and the third straight groove of the first etch window perpendicularly and respectively extend toward the second etch window from the two terminals of the first straight groove of the first etch window;
the second etch window comprises a first straight groove, a second straight groove, and a third straight groove, the first straight groove of the second etch window is parallel to the first straight groove of the first etch window and has two terminals opposite to each other, and the second straight groove and the third straight groove of the second etch window perpendicularly and respectively extend toward the first etch window from the two terminals of the first straight groove of the second etch window;
the second insulating layer has the suspension part formed in a region surrounded by the first straight groove and the second straight groove of the first etch window and the first straight groove and the third straight groove of the second etch window;
the at least one supporting part comprises a first supporting part and a second supporting part respectively connected to opposite sides of the suspension part;
the second insulating layer has the first supporting part formed in a region between the second straight groove of the first etch window and the second straight groove of the second etch window;
the second insulating layer has the second supporting part formed in a region between the third straight groove of the first etch window and the third straight groove of the second etch window;
the sensing layer is formed on the top surface of the suspension part and the top surfaces of the first supporting part and the second supporting part of the second insulating layer.

4. The thermal barometric altimeter as claimed in claim 3, wherein the sensing layer is a component made of an electrically conductive material and resistance of the sensing layer is a function of temperature.

5. The thermal barometric altimeter as claimed in claim 3, wherein the sensing layer on the suspension part is a continuously bent configuration comprising multiple bent segments.

6. The thermal barometric altimeter as claimed in claim 2 further comprising a heating resistor layer, wherein
the sensing layer is a thermocouple layer;
the at least one etch window comprises a first etch window, a second etch window, a third etch window, and a fourth etch window;
the first etch window is opposite to the second etch window and comprises
a first straight groove; and
a second straight groove perpendicularly extending toward the second etch window from the first straight groove of the first etch window;
the second etch window comprises
a first straight groove parallel to the first straight groove of the first etch window; and
a second straight groove perpendicularly extending toward the first etch window from the first straight groove of the second etch window and dislocated from and parallel to the second straight groove of the first etch window;
the third etch window and the fourth etch window are between the first etch window and the second etch window;
the third etch window is opposite to the fourth etch window and comprises
a first straight groove; and
a second straight groove perpendicularly extending toward the fourth etch window from the first straight groove of the third etch window;
the fourth etch window comprises
a first straight groove parallel to the first straight groove of the third etch window; and
a second straight groove perpendicularly extending toward the third etch window from the first straight groove of the fourth etch window and dislocated from and parallel to the second straight groove of the third etch window;
the second insulating layer has the suspension part formed in a region surrounded by the second straight grooves of the first to fourth etch windows;
the at least one supporting part comprises a first supporting part, a second supporting part, a third supporting part, and a fourth supporting part;
the second insulating layer has the first supporting part formed in a region between the first straight groove of the first etch window and the second straight groove of the fourth etch window;
the second insulating layer has the second supporting part formed in a region between the first straight groove of the third etch window and the second straight groove of the first etch window;
the second insulating layer has the third supporting part formed in a region between the first straight groove of the second etch window and the second straight groove of the third etch window;
the second insulating layer has the fourth supporting part formed in a region between the first straight groove of the fourth etch window and the second straight groove of the second etch window;
the sensing layer is formed on the top surface of the suspension part and the top surfaces of the third supporting part and the fourth supporting part of the second insulating layer; and
the heating resistor layer is formed on the top surface of the suspension part and the top surfaces of the first supporting part and the second supporting part of the second insulating layer.

7. The thermal barometric altimeter as claimed in claim 6, wherein
the sensing layer on the suspension part is a continuously bent configuration comprising multiple bent segments;
the heating resistor layer on the suspension part is a continuously bent configuration comprising multiple bent segments;
the multiple bent segments of the sensing layer and the multiple bent segments of the heating resistor layer are alternately disposed.

8. The thermal barometric altimeter as claimed in claim 2 further comprising a heating resistor layer, wherein
the sensing layer is a thermocouple layer;
the at least one etch window comprises a first etch window, a second etch window, a third etch window, and a fourth etch window;
the first etch window is opposite to the second etch window and comprises
a first straight groove; and
a second straight groove perpendicularly extending toward the second etch window from the first straight groove of the first etch window;
the second etch window comprises
a first straight groove parallel to the first straight groove of the first etch window; and
a second straight groove perpendicularly extending toward the first etch window from the first straight groove of the second etch window and dislocated from and parallel to the second straight groove of the first etch window;
the third etch window and the fourth etch window are between the first etch window and the second etch window;
the third etch window is opposite to the fourth etch window and comprises
a first straight groove; and
a second straight groove perpendicularly extending toward the fourth etch window from the first straight groove of the third etch window;
the fourth etch window comprises
a first straight groove parallel to the first straight groove of the third etch window; and
a second straight groove perpendicularly extending toward the third etch window from the first straight groove of the fourth etch window and dislocated from and parallel to the second straight groove of the third etch window;
the second insulating layer has the suspension part formed in a region surrounded by the second straight grooves of the first to fourth etch windows;
the at least one supporting part comprises a first supporting part, a second supporting part, a third supporting part, and a fourth supporting part;
the second insulating layer has the first supporting part formed in a region between the first straight groove of the first etch window and the second straight groove of the fourth etch window;
the second insulating layer has the second supporting part formed in a region between the first straight groove of the third etch window and the second straight groove of the first etch window;
the second insulating layer has the third supporting part formed in a region between the first straight groove of the second etch window and the second straight groove of the third etch window;
the second insulating layer has the fourth supporting part formed in a region between the first straight groove of the fourth etch window and the second straight groove of the second etch window;
the heating resistor layer is formed on the top surface of the suspension part and the top surfaces of the third supporting part and the fourth supporting part of the second insulating layer;
the sensing layer comprises
a first thermocouple member having a first terminal formed on the first supporting part and a second terminal formed on the suspension part;
a second thermocouple member having a first terminal formed on the second supporting part and a second terminal formed on the suspension part; and
the second terminal of the first thermocouple member and the second terminal of the second thermocouple member are connected to each other to form a junction.

9. The thermal barometric altimeter as claimed in claim 8, wherein
the heating resistor layer on the suspension part is a continuously bent configuration comprising multiple bent segments;
the junction is located in one of the multiple bent segments.

10. The thermal barometric altimeter as claimed in claim 2, wherein
the at least one etch window is an etch window comprising a first straight groove, a second straight groove, and a third straight groove; the first straight groove has two terminals opposite to each other, and the second straight groove and the third straight groove perpendicularly and respectively extend toward a same direction from the two terminals of the first straight groove;
the at least one supporting part is a supporting part;
the second insulating layer has the suspension part and the supporting part formed in a region between the second straight groove and the third straight groove;
the suspension part is closer to the first straight groove than the suspension part;
the sensing layer is formed on the top surfaces of the suspension part and the supporting part.

11. The thermal barometric altimeter as claimed in claim 10, wherein the sensing layer is a component made of an electrically conductive material and resistance of the sensing layer is a function of temperature.

12. The thermal barometric altimeter as claimed in claim 10, wherein the sensing layer on the suspension part is a continuously bent configuration comprising multiple bent segments.

13. The thermal barometric altimeter as claimed in claim 1, wherein the suspension structure comprises an outer insulating layer formed on the suspension part and the at least one supporting part and covering the sensing layer.

14. The thermal barometric altimeter as claimed in claim 2, wherein the suspension structure comprises an outer insulating layer formed on the suspension part and the at least one supporting part and covering the sensing layer.

15. The thermal barometric altimeter as claimed in claim 3, wherein the suspension structure comprises an outer insulating layer formed on the suspension part and the at least one supporting part and covering the sensing layer.

16. The thermal barometric altimeter as claimed in claim 4, wherein the suspension structure comprises an outer insulating layer formed on the suspension part and the at least one supporting part and covering the sensing layer.

17. The thermal barometric altimeter as claimed in claim 6, wherein the suspension structure comprises an outer insulating layer formed on the suspension part and the at least one supporting part and covering the sensing layer.

18. The thermal barometric altimeter as claimed in claim 8, wherein the suspension structure comprises an outer insulating layer formed on the suspension part and the at least one supporting part and covering the sensing layer.

19. The thermal barometric altimeter as claimed in claim 9, wherein the suspension structure comprises an outer insulating layer formed on the suspension part and the at least one supporting part and covering the sensing layer.

20. The thermal barometric altimeter as claimed in claim 10, wherein the suspension structure comprises an outer insulating layer formed on the suspension part and the at least one supporting part and covering the sensing layer.
